(19) United States
(12) Patent Application Publication
(10) Pub. No.: US 2022/0384280 A1
(43) Pub. Date: Dec. 1, 2022

(54) SEMICONDUCTOR STRUCTURE

(71) Applicant: Changxin Memory Technologies, Inc., Hefei (CN)

(72) Inventors: Tzung-Han LEE, HEFEI (CN); ChihCheng LIU, HEFEI (CN)

(21) Appl. No.: 17/568,375

(22) Filed: Jan. 4, 2022

Related U.S. Application Data
(63) Continuation of application No. PCT/CN2021/120401, filed on Sep. 24, 2021.

(30) Foreign Application Priority Data
Jun. 1, 2021 (CN) 202110609507.7

(51) Int. Cl. H01L 21/66

(52) U.S. Cl. CPC H01L 22/32

(57) ABSTRACT

A semiconductor structure including a semiconductor base and a test element group is provided. The test element group includes a first metal layer, a second metal layer, and a through-silicon via. The first metal layer is located on the semiconductor base. Reserved space running through the first metal layer is formed on the first metal layer. The second metal layer is located above the first metal layer and is spaced away from the first metal layer. The through-silicon via is located inside the semiconductor base and runs through the reserved space, and the through-silicon via is connected to the second metal layer. The cross-sectional area of the through-silicon via is less than the cross-sectional area of the reserved space, so that the through-silicon via is spaced away from the first metal layer.

### CROSS-REFERENCE TO RELATED APPLICATIONS

This application is a continuation application of International Patent Application No.: PCT/CN2021/120401, filed on Sep. 24, 2021, which claims priority to Chinese Patent Application No.: 202110609507.7, filed on Jun. 1, 2021. The above-referenced applications are incorporated herein by reference in their entirety.

### TECHNICAL FIELD

The present invention relates generally to the field of semiconductor technologies, and in particular, to a semiconductor structure.

### BACKGROUND

As functionalization of semiconductor devices reaches a higher degree, it is particularly imperative to evaluate structures and assembly processes of semiconductors by using test element group (TEG) chips.

### SUMMARY

The present invention provides a semiconductor structure to facilitate the test of the performance of a through-silicon via.

An embodiment of this invention provides a semiconductor structure, including a semiconductor base and a test element group. The test element group includes a first metal layer, a second metal layer, and a through-silicon via. The first metal layer is located on the semiconductor base. Reserved space running through the first metal layer is formed on the first metal layer. The second metal layer is located above the first metal layer and is spaced away from the first metal layer. The through-silicon via is located inside the semiconductor base and runs through the reserved space, and the through-silicon via is connected to the second metal layer. The cross-sectional area of the through-silicon via is less than the cross-sectional area of the reserved space, so that the through-silicon via is spaced away from the first metal layer.

### BRIEF DESCRIPTION OF THE DRAWINGS

The purposes, features and advantages of the present invention will become apparent from the following detailed descriptions of preferred embodiments of the present invention when considered with reference to the accompanying drawings. The accompanying drawings are merely exemplary illustrations of the present invention, and are not necessarily drawn to scale. In the accompanying drawings, the same reference numerals always represent the same or similar components.

FIG. 1 is a schematic structural diagram of a test element group of a semiconductor structure according to an embodiment of this invention.

FIG. 2 is a schematic structural diagram of a first metal layer and a through-silicon via of a semiconductor structure according to an embodiment of this invention.

FIG. 3 is a schematic structural diagram of a second metal layer of a semiconductor structure according to an embodiment of this invention.

FIG. 4 is a schematic structural diagram of a first conductive via and a second conductive via of a semiconductor structure according to an embodiment of this invention.

FIG. 5 is a schematic structural diagram of a third metal layer of a semiconductor structure according to an embodiment of this invention.

FIG. 6 is a schematic structural diagram of a third conductive via of a semiconductor structure according to an embodiment of this invention.

FIG. 7 is a schematic structural diagram of a fourth metal layer of a semiconductor structure according to an embodiment of this invention.

FIG. 8 is a schematic structural diagram of a fourth conductive via of a semiconductor structure according to an embodiment of this invention.

FIG. 9 is a schematic structural diagram of a fifth metal layer of a semiconductor structure according to an embodiment of this invention.

FIG. 10 is a schematic structural diagram of a fifth conductive via of a semiconductor structure according to an embodiment of this invention.

Reference numerals represent the following: 1. test element group; 10. first metal layer; 11. reserved space; 20. second metal layer; 21. first conductive via; 22. second conductive via; 30. through-silicon via; 40. third metal layer; 41. third conductive via; 50. fourth metal layer; 51. fourth conductive via; 60. fifth metal layer; 61. fifth conductive via.

### DETAILED DESCRIPTION OF THE EMBODIMENTS

Typical exemplary embodiments embodying features and advantages of the present invention will be described in detail in the following descriptions. Various changes can be made to the present invention in different embodiments, which do not depart from the scope of the present invention. The descriptions and accompanying drawings thereof are merely for illustrative purposes, rather than limiting the present invention.

In the following descriptions of different exemplary embodiments of the present invention, reference is made to the accompanying drawings. The accompanying drawings illustrate different exemplary structures, systems and steps of various aspects of the present invention. It should be understood that other specific solutions of components, structures, exemplary apparatuses, systems, and steps may be used to make structural and functional modifications without departing from the scope of the present invention. Moreover, terms such as “above”, “between”, and “within” may be used in this specification to describe different exemplary features and elements of the present invention. However, these terms are merely used for the convenience of explanation. The exemplary direction in the accompanying drawings is an example. Nothing in this specification should be understood as requiring a specific three-dimensional direction of a structure to fall within the scope of the present invention.

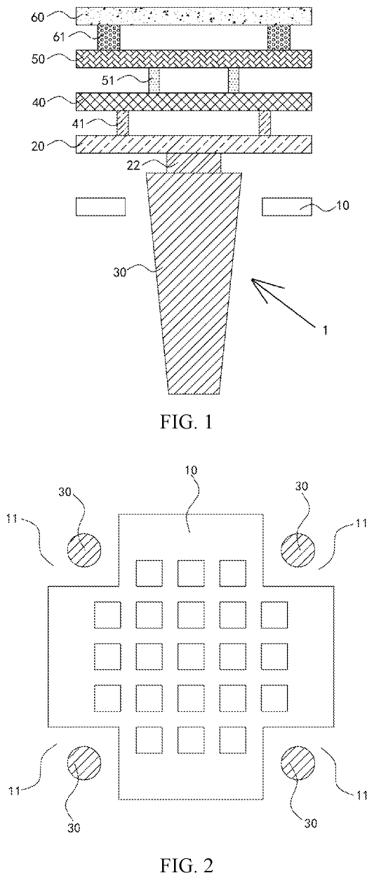

Referring to FIGS. 1, 2, and 3, the semiconductor structure according to an embodiment of this invention includes a semiconductor base and a test element group 1. The test element group 1 includes a first metal layer 10, a second metal layer 20, and a through-silicon via 30. The first metal layer 10 is located on the semiconductor base. A reserved space 11 is formed on the first metal layer 10, and the reserved space 11 runs through the upper surface and lower surface of the first metal layer 10. The second metal layer 20 is located above the first metal layer 10 and is spaced away from the first metal layer 10. The through-silicon via 30 is located inside the semiconductor base and runs through the reserved space 11, and the through-silicon via 30 is connected to the second metal layer 20. The cross-sectional area of the through-silicon via 30 is less than the cross-sectional area of the reserved space 11, so that the through-silicon via 30 is spaced away from the first metal layer 10.

The semiconductor structure in this embodiment of the present invention includes the semiconductor base and the test element group 1. The test element group 1 includes the first metal layer 10, the second metal layer 20, and the through-silicon via 30. By forming the reserved space 11 on the first metal layer 10, the through-silicon via 30 may be connected to the second metal layer 20 after running through the reserved space 11. In addition, the through-silicon via 30 is not connected to the first metal layer 10. Therefore, the through-silicon via 30 can be tested by a test device connecting to the second metal layer 20.

It should be noted that the semiconductor structure includes an actual device wafer and a test element group 1. The actual device wafer can be tested by using the test element group 1. In other words, the test element group 1 becomes a detection wafer or a test wafer. In this embodiment, the actual device wafer includes a structure approximately the same as that of the through-silicon via 30 in this embodiment. Therefore, the performance of a through-silicon via of the actual device wafer may be obtained by detecting the performance of the through-silicon via 30 (TSV) of the test element group 1.

In some embodiments, the distribution layer of the test element group 1 may include only the first metal layer 10 and the second metal layer 20. Since the second metal layer 20 is connected to the through-silicon via 30, the second metal layer 20 may be provided with a test pad such that the through-silicon via 30 may be tested by using a probe connecting to a corresponding test pad (i.e., the test pad connected to the through-silicon via 30).

In an embodiment, the semiconductor base includes a substrate. The first metal layer 10 is located above the substrate. The test element group 1 may further include a contact hole. Two ends of the contact hole are respectively connected to the first metal layer 10 and the substrate. The semiconductor base may further include an insulation layer. The test element group 1 may be located inside the insulation layer, and the insulation layer may protect and isolate the test element group 1. The through-silicon via 30 runs through the substrate. The through-silicon via 30 may be formed after the first metal layer 10 is formed. Therefore, the reserved space 11 formed on the first metal layer 10 can ensure the formation of the through-silicon via 30.

In an embodiment, the reserved space 11 may be formed in the middle portion of the first metal layer 10. In other words, the reserved space 11 has side walls that are circumferentially closed.

In an embodiment, the reserved space 11 may be provided on the edge of the first metal layer 10.

The reserved space 11 may be located on the outer side of the first metal layer 10. In other words, the side walls of the reserved space 11 are not circumferentially closed. In this specification, a space has side walls that are “circumferentially closed” may mean the side walls fully enclose the space, and there is no pathway to the exterior through the side walls.

In some embodiments, the semiconductor structure may include a plurality of reserved spaces 11 and a plurality of through-silicon vias 30. The plurality of through-silicon vias 30 may respectively run through the corresponding reserved spaces 11 to be connected to the second metal layer 20. In some embodiments, at least one of the plurality of reserved spaces 11 is located at a corner region of the first metal layer 10 to ensure that the structure of the first metal layer 10 is not too complex, thereby reducing manufacturing costs.

Referring to FIG. 2, each of the reserved spaces 11 has a rectangle shape, and the reserved spaces 11 are respectively formed at the four corner regions of the first metal layer 10, which is similar to cutting off four corners of a rectangle structure, to form four reserved spaces 11 to ensure that the corresponding through-silicon vias 30 may pass through.

Referring to FIG. 4, the test element group 1 further includes a first conductive via 21. Two ends of the first conductive via 21 are respectively connected to the first metal layer 10 and the second metal layer 20, so that the first metal layer 10 can be connected to the second metal layer 20 through the first conductive via 21.

In some embodiments, the first conductive via 21 may have a contact hole structure or a through-hole structure.

Further referring to FIG. 4, the test element group 1 may further include a second conductive via 22. Two ends of the second conductive via 22 are respectively connected to the through-silicon via 30 and the second metal layer 20. In other words, the through-silicon via 30 may be connected to the second metal layer 20 through the second conductive via 22, so as to ensure the stability of the connection and reduce the length of the through-silicon via 30.

In some embodiments, the second conductive via 22 may have a contact hole structure. The semiconductor structure may include a plurality of second conductive vias 22, and the plurality of second conductive vias 22 may correspond to the plurality of through-silicon vias 30.

In some embodiments, the cross-sectional area of the first conductive via 21 is less than the cross-sectional area of the second conductive via 22. In consideration of the structural characteristics of the through-silicon via 30 and to ensure a reliable connection of the through-silicon via 30, the cross-sectional area of the second conductive via 22 is relatively large. The first conductive via 21 is configured to be connected to the adjacent first metal layer 10 and the second metal layer 20, and the line widths of the first metal layer 10 and the second metal layer 20 are relatively small. Therefore, the cross-sectional area of the first conductive via 21 may be smaller, thereby reducing the space occupancy and simplifying the structure.

In this specification, the cross-sectional area of a conductive via may refer to an area of the conductive via that is cut by a plane parallel with a top surface of the substrate. For example, as shown in FIG. 4, the cross-sectional areas of the first conductive via 21 and the second conductive via 22 may refer to, respectively, the shaded rectangle area 21 and the shaded rectangle area 22.

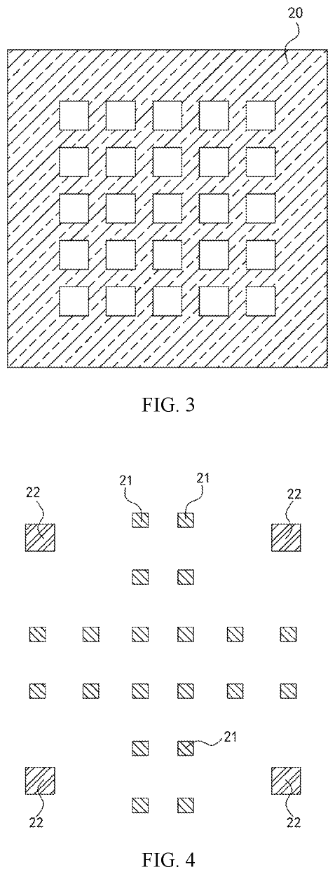

Referring to FIGS. 2 and 3, the first metal layer 10 and the second metal layer 20 may have a grid structure.

Referring to FIGS. 1, 5, and 6, the test element group 1 according to an embodiment of this invention further includes a third metal layer 40 and a third conductive via 41. The third metal layer 40 is located above the second metal layer 20 and is spaced away from the second metal layer 20. Two ends of the third conductive via 41 are respectively connected to the second metal layer 20 and the third metal layer 40. In other words, the second metal layer 20 is connected to the third metal layer 40 through the third conductive via 41. In this case, the through-silicon via 30 may be connected to the third metal layer 40, and the through-silicon via 30 may be detected by using a probe connecting to a test pad on the third metal layer 40.

In some embodiments, the distribution layer of the test element group 1 may include only the first metal layer 10, the second metal layer 20, and the third metal layer 40. Considering that the second metal layer 20 is connected to the through-silicon via 30 and the third metal layer 40 is connected to the second metal layer 20 through the third conductive via 41 (namely, the third metal layer 40 is electrically connected to the through-silicon via 30), the third metal layer 40 may be provided with a test pad such that the through-silicon via 30 may be tested by using a probe connecting to a corresponding test pad.

Further, the third metal layer 40 may be a redistribution layer (RDL). That is, connection pads on the second metal layer 20 and the first metal layer 10 may be led out by using the third metal layer 40 to facilitate subsequent test use. In some embodiments, the cross-sectional area of the first conductive via 21 is less than the cross-sectional area of the third conductive via 41. Correspondingly, the line width of the third metal layer 40 is relatively large, so as to ensure that the third metal layer 40 reliably covers the third conductive via 41 and ensure a reliable connection to the second metal layer 20. The line width of the redistribution layer is greater than the line width of any of the first metal layer 10 and the second metal layer 20.

In an embodiment, projections of the first conductive via 21 and the third conductive via 41 on a plane parallel with the top surface of the semiconductor base at least partially do not overlap. The top surface of the semiconductor base may be a horizontal plane. In other words, the first conductive via 21 and the third conductive via 41 are arranged in a staggered manner vertically. Considering that the first conductive via 21 and the third conductive via 41 are respectively connected to two opposite surfaces of the second metal layer 20, the first conductive via 21 and the third conductive via 41 may be arranged in a staggered manner vertically to avoid stress concentration at one position, thereby ensuring the stability and prolonging the service life of the semiconductor structure. In some embodiments, projections of the second conductive via 22 and the third conductive via 41 on a plane parallel with the top surface of the semiconductor base at least partially do not overlap.

Further, the semiconductor structure may include a plurality of first conductive vias 21, a plurality of second conductive vias 22, and a plurality of third conductive vias 41. The third conductive via 41 may have a through-hole structure.

In some embodiments, projections of the first conductive via 21 and the third conductive via 41 on a plane parallel with the top surface of the semiconductor base may overlap. In other words, structures of the first conductive via 21 and the third conductive via 41 may be completely the same.

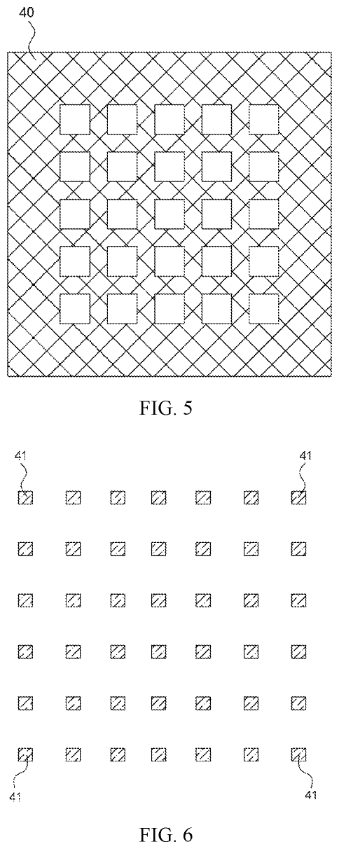

Referring to FIG. 5, the third metal layer 40 may have a grid structure.

Referring to FIGS. 1, 7, and 8, the test element group 1 according to an embodiment of this invention further includes a fourth metal layer 50 and a fourth conductive via 51. The fourth metal layer 50 is located above the third metal layer 40 and is spaced away from the third metal layer 40. Two ends of the fourth conductive via 51 are respectively connected to the third metal layer 40 and the fourth metal layer 50. In other words, the third metal layer 40 is connected to the fourth metal layer 50 through the fourth conductive via 51. In this case, the through-silicon via 30 may be connected to the fourth metal layer 50, and the through-silicon via 30 may be detected by using a probe connecting to a test pad on the fourth metal layer 50.

In some embodiments, the distribution layer of the test element group 1 may include only the first metal layer 10, the second metal layer 20, the third metal layer 40, and the fourth metal layer 50. Considering that the second metal layer 20 is connected to the through-silicon via 30, the third metal layer 40 is connected to the second metal layer 20 through the third conductive via 41, and the fourth metal layer 50 is connected to the third metal layer 40 through the fourth conductive via 51 (namely, the fourth metal layer 50 is electrically connected to the through-silicon via 30), the fourth metal layer 50 may be provided with a test pad such that the through-silicon via 30 may be tested by using a probe connecting to a corresponding test pad.

Further, the fourth metal layer 50 may be a redistribution layer, that is, connection pads on the third metal layer 40, the second metal layer 20, and the first metal layer 10 may be led out by using the fourth metal layer 50 to facilitate subsequent test use. In some embodiments, the cross-sectional area of the third conductive via 41 is less than the cross-sectional area of the fourth conductive via 51. Correspondingly, the line width of the fourth metal layer 50 is relatively large, so as to ensure that the fourth metal layer 50 reliably covers the fourth conductive via 51 and ensure a reliable connection to the third metal layer 40. The line width of the redistribution layer is greater than the line width of any of the first metal layer 10, the second metal layer 20, and the third metal layer 40.

In an embodiment, projections of the third conductive via 41 and the fourth conductive via 51 on a plane parallel with the top surface of the semiconductor base at least partially do not overlap. In other words, the third conductive via 41 and the fourth conductive via 51 are arranged in a staggered manner vertically. Considering that the third conductive via 41 and the fourth conductive via 51 are respectively connected to two opposite surfaces of the third metal layer 40, the third conductive via 41 and the fourth conductive via 51 may be arranged in a staggered manner vertically to avoid stress concentration at one position, thereby ensuring the stability and prolonging the service life of the semiconductor structure.

Further, the semiconductor structure may include a plurality of third conductive vias 41 and a plurality of fourth conductive vias 51. The third conductive via 41 and the fourth conductive via 51 may have a through-hole structure.

In some embodiments, projections of the third conductive via 41 and the fourth conductive via 51 on a plane parallel with the top surface of the semiconductor base may overlap. In other words, structures of the third conductive via 41 and the fourth conductive via 51 may be completely the same.

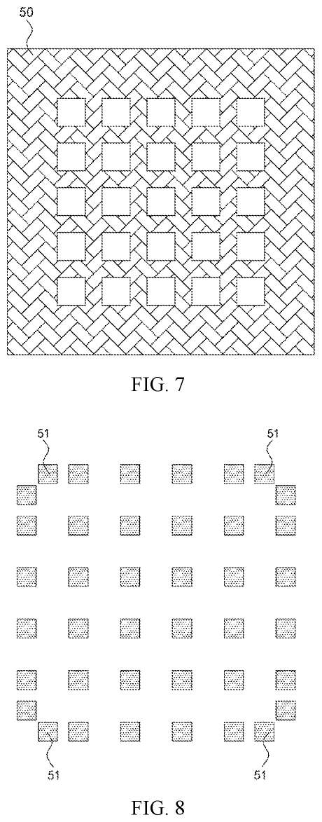

Referring to FIG. 7, the fourth metal layer 50 may have a grid structure.

Referring to FIGS. 1, 9, and 10, the test element group 1 according to an embodiment of this invention further includes a fifth metal layer 60 and a fifth conductive via 61. The fifth metal layer 60 is located above the fourth metal layer 50 and is spaced away from the fourth metal layer 50. Two ends of the fifth conductive via 61 are respectively connected to the fourth metal layer 50 and the fifth metal layer 60. In other words, the fourth metal layer 50 is connected to the fifth metal layer 60 through the fifth conductive via 61. In this case, the through-silicon via 30 may be connected to the fifth metal layer 60, and the through-silicon via 30 may be detected by using a probe connecting to a test pad on the fifth metal layer 60.

In some embodiments, the distribution layer of the test element group 1 may include only the first metal layer 10, the second metal layer 20, the third metal layer 40, the fourth metal layer 50, and the fifth metal layer 60. Considering that the second metal layer 20 is connected to the through-silicon via 30, the third metal layer 40 is connected to the second metal layer 20 through the third conductive via 41, the fourth metal layer 50 is connected to the third metal layer 40 through the fourth conductive via 51, and the fifth metal layer 60 is connected to the fourth metal layer 50 through the fifth conductive via 61 (namely, the fifth metal layer 60 is electrically connected to the through-silicon via 30), the fifth metal layer 60 may be provided with a test pad such that the through-silicon via 30 may be tested by using a probe connecting to a corresponding test pad.

Further, the fifth metal layer 60 may be a redistribution layer, that is, connection pads on the fourth metal layer 50, the third metal layer 40, the second metal layer 20, and the first metal layer 10 may be led out by using the fifth metal layer 60 to facilitate subsequent test use. In some embodiments, the cross-sectional area of the fourth conductive via 51 is less than the cross-sectional area of the fifth conductive via 61. Correspondingly, the line width of the fifth metal layer 60 is relatively large, so as to ensure that the fifth metal layer 60 completely covers the fifth conductive via 61 and ensure a reliable connection to the fourth metal layer 50. The line width of the redistribution layer is greater than the line width of any of the first metal layer 10, the second metal layer 20, the third metal layer 40, and the fourth metal layer 50. In an embodiment, projections of the fourth conductive via 51 and the fifth conductive via 61 on a plane parallel with the top surface of the semiconductor base at least partially do not overlap. In other words, the fourth conductive via 51 and the fifth conductive via 61 are arranged in a staggered manner vertically. Considering that the fourth conductive via 51 and the fifth conductive via 61 are respectively connected to two opposite surfaces of the fourth metal layer 50, the fourth conductive via 51 and the fifth conductive via 61 may be arranged in a staggered manner vertically to avoid stress concentration at one position, thereby ensuring the stability and prolonging the service life of the semiconductor structure.

Further, the semiconductor structure may include a plurality of fourth conductive vias 51 and a plurality of fifth conductive vias 61. The fourth conductive via 51 and the fifth conductive via 61 may have a through-hole structure.

In some embodiments, projections of the fourth conductive via 51 and the fifth conductive via 61 on a plane parallel with the top surface of the semiconductor base may overlap. In other words, structures of the fourth conductive via 51 and the fifth conductive via 61 may be completely the same.

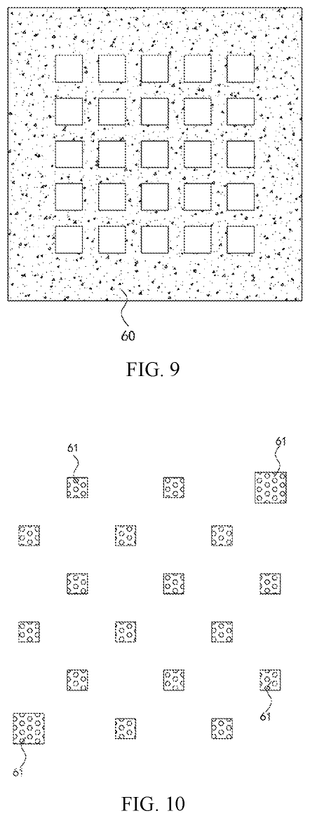

Referring to FIG. 9, the fifth metal layer 60 may have a grid structure.

The test element group 1 according to an embodiment of the present invention may further include a sixth metal layer, a seventh metal layer, and the like. The structure of the test element group 1 is not limited herein and may be determined based on an actual need to reliably lead out various conductive connection structures. The uppermost metal layer may be a redistribution layer.

A person skilled in the art can easily figure out other embodiments of the present invention after considering the specification and practicing the present invention disclosed herein. The present invention is intended to cover any modifications, uses, or adaptive changes hereof. These modifications, uses, or adaptive changes follow the general principles of the present invention and include common knowledge or conventional technical means in the technical field that are not disclosed in the present invention. The specification and exemplary embodiments herein are merely for illustrative purpose, while the true scope and spirit of the present invention are indicated by the appended claims.

It should be understood that the present invention is not limited to the precise structures described above and shown in the accompanying drawings, and various modifications and changes can be made without departing from the scope of the present invention. The scope of the present invention is limited only by the appended claims.

What is claimed is:

1. A semiconductor structure, comprising a semiconductor base and a test element group, wherein the test element group comprises:
a first metal layer located on the semiconductor base, wherein a reserved space is formed through the first metal layer;
a second metal layer located above the first metal layer and spaced away from the first metal layer; and
a through-silicon via located inside the semiconductor base and running through the reserved space, wherein the through-silicon via is connected to the second metal layer, and wherein a cross-sectional area of the through-silicon via is less than a cross-sectional area of the reserved space, so that the through-silicon via is spaced away from the first metal layer.

2. The semiconductor structure of claim 1, wherein the reserved space is provided at an edge of the first metal layer.

3. The semiconductor structure of claim 2, further comprising a plurality of reserved spaces and a plurality of through-silicon vias, wherein at least one of the plurality of reserved spaces is located at a corner region of the first metal layer.

4. The semiconductor structure of claim 3, wherein each of the plurality of reserved spaces has a rectangle shape, and the reserved spaces are respectively formed at four corner regions of the first metal layer.

5. The semiconductor structure of claim 1, wherein the test element group further comprises:
a first conductive via, wherein two ends of the first conductive via are respectively connected to the first metal layer and the second metal layer.

6. The semiconductor structure of claim 5, wherein the test element group further comprises:
a second conductive via, wherein two ends of the second conductive via are respectively connected to the through-silicon via and the second metal layer.

7. The semiconductor structure of claim 6, wherein a cross-sectional area of the first conductive via is less than a cross-sectional area of the second conductive via.

8. The semiconductor structure of claim 5, wherein the test element group further comprises:
a third metal layer located above the second metal layer and spaced away from the second metal layer; and
a third conductive via, wherein two ends of the third conductive via are respectively connected to the second metal layer and the third metal layer.

9. The semiconductor structure of claim 8, wherein at least a portion of a projection of the first conductive via and at least a portion of a projection of the third conductive via on a plane parallel with a top surface of the semiconductor base do not overlap.

10. The semiconductor structure of claim 8, wherein the test element group further comprises:
a fourth metal layer located above the third metal layer and spaced away from the third metal layer; and
a fourth conductive via, wherein two ends of the fourth conductive via are respectively connected to the third metal layer and the fourth metal layer.

11. The semiconductor structure of claim 10, wherein at least a portion of a projection of the third conductive via and at least a portion of a projection of the fourth conductive via on a plane parallel with a top surface of the semiconductor base do not overlap.

12. The semiconductor structure of claim 10, wherein the test element group further comprises:
a fifth metal layer located above the fourth metal layer and spaced away from the fourth metal layer; and
a fifth conductive via, wherein two ends of the fifth conductive via are respectively connected to the fourth metal layer and the fifth metal layer.

13. The semiconductor structure of claim 12, wherein at least a portion of a projection of the fourth conductive via and at least a portion of a projection of the fifth conductive via on a plane parallel with a top surface of the semiconductor base do not overlap.

14. The semiconductor structure of claim 12, wherein the fifth metal layer is a redistribution layer.

15. The semiconductor structure of claim 14, wherein a cross-sectional area of the fourth conductive via is less than a cross-sectional area of the fifth conductive via.

16. The semiconductor structure of claim 14, wherein a line width of the redistribution layer is greater than a line width of any one of the first metal layer, the second metal layer, the third metal layer, and the fourth metal layer.

17. The semiconductor structure of claim 12, wherein at least one of the first metal layer, the second metal layer, the third metal layer, the fourth metal layer, and the fifth metal layer has a grid structure.

18. The semiconductor structure of claim 8, wherein the third metal layer is a redistribution layer; and
a cross-sectional area of the first conductive via is less than a cross-sectional area of the third conductive via.

19. The semiconductor structure of claim 10, wherein the fourth metal layer is a redistribution layer; and
a cross-sectional area of the third conductive via is less than a cross-sectional area of the fourth conductive via.

20. The semiconductor structure of claim 12, wherein at least one of the first conductive via, the third conductive via, the fourth conductive via, and the fifth conductive via has a through-hole structure.
